(19) United States
(12) Patent Application Publication
(10) Pub. No.: US 2014/0235016 A1
(43) Pub. Date: Aug. 21, 2014

(54) METHOD OF FABRICATING SEMICONDUCTOR PACKAGE

(71) Applicants: SIGETRONICS Inc., Jeonju-si (KR); Electronics and Telecommunications Research Institute, Daejeon (KR)

(72) Inventors: Jong-Moon PARK, Daejeon (KR); Jin Ho LEE, Daejeon (KR); Deok-Ho CHO, Seoul (KR); Kyu-Hwan SHIM, Jeonju-si (KR)

(73) Assignees: SIGETRONICS Inc., Jeonju-si (KR); Electronics and Telecommunications Research Institute, Daejeon (KR)

(21) Appl. No.: 14/155,243

(22) Filed: Jan. 14, 2014

(30) Foreign Application Priority Data
Feb. 21, 2013 (KR) 10-2013-0018756

(51) Int. Cl. H01L 23/00

(52) U.S. Cl. CPC H01L 24/80
USPC 438/106

(57) ABSTRACT

Provided is a method of fabricating a semiconductor package, including preparing a die including a first metal layer and a second metal layer which are sequentially stacked on a silicon substrate, preparing a package substrate including a lead frame, and forming an adhesive layer between the lead frame and the first metal layer and attaching the die to the package substrate, wherein the forming of the adhesive layer is performed by eutectic bonding between the silicon substrate and the second metal layer. According to the semiconductor package according to an embodiment of the present invention, an adhesive layer can be easily formed by eutectic bonding without a process of forming a preform.

### CROSS-REFERENCE TO RELATED APPLICATIONS

This U.S. non-provisional patent application claims priority under 35 U.S.C. § 119 of Korean Patent Application No. 10-2013-0018756, filed on Feb. 21, 2013, the entire contents of which are hereby incorporated by reference.

### BACKGROUND OF THE INVENTION

The present invention disclosed herein relates to a semiconductor package and a fabricating method of the same, and more particularly, to a semiconductor package mounted by eutectic bonding.

According to high density and high integration of semiconductor integrated circuits used in electronic devices, semiconductors having electrode terminals of multi-pins and fine pitch are being rapidly developed. In order to reduce interconnection delays, a flip-chip bonding mounting technology is widely used for mounting semiconductor chips on a circuit board

A die may be attached to a substrate or a lead frame by adhesive bonding using an epoxy adhesive, glass frit attach, and/or eutectic bonding. A semiconductor device packaged by using an epoxy adhesive or solder may have low strength between the die and the package substrate. Accordingly, when a die having a small area is mounted, eutectic bonding is widely used for semiconductor packaging. The eutectic bonding may be also applied in a process of fabricating a sensitive discrete devices.

### SUMMARY OF THE INVENTION

The present invention provides a semiconductor package having improved reliability and a fabricating method of the same.

The present invention also provides a semiconductor package fabricated in a simplified process and showing an improved yield, and a fabricating method of the same.

Embodiments of the present invention provide methods of fabricating a semiconductor package, including: preparing a die including a first metal layer and a second metal layer which are sequentially stacked on a silicon substrate; preparing a package substrate including a lead frame; and forming an adhesive layer between the lead frame and the first metal layer to attach the die to the package substrate, wherein the adhesive layer is formed by eutectic bonding of the silicon substrate to the second metal layer.

In some embodiments, the adhesive layer may include silicon and the same material as that of the second metal layer.

In other embodiments, the adhesive layer may further include the same material as that of the first metal layer.

In still other embodiments, the forming of the adhesive layer may include: facing down the die on the package substrate and contacting the second metal layer to the lead frame; and heating the die and the package substrate.

In even other embodiments, the heating may be performed under a temperature condition of about 370 to about 450° C.

In yet other embodiments, the preparing of the die may include: depositing titanium or chromium on the silicon substrate to form the first metal layer; and depositing gold on the first metal layer to form the second metal layer.

In further embodiments, the first metal layer may have about 25 to about 300 Å thickness.

In still further embodiments, the second metal layer has about 3,000 to about 10,000 Å thickness.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a semiconductor package according to an embodiment of the present invention; and

FIGS. 2 to 5 are cross-sectional views illustrating a fabricating method of an semiconductor package according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will also be understood that when a layer is referred to as being “on” another layer or substrate, it can be directly on the other layer or substrate, or intervening layers may also be present.

It will be understood that, although the terms first, second, third etc. may be used herein to describe various elements, components, regions, layers and/or sections, these elements, components, regions, layers and/or sections should not be limited by these terms. These terms are used only to tell one region or layer from another region or layer. Therefore, a layer referred to as a first layer in one embodiment can be referred to as a second layer in another embodiment. An embodiment described and exemplified herein includes a complementary embodiment thereof Like reference numerals refer to like elements throughout.

Unless otherwise defined, all terms used herein have the same meaning as commonly understood by one of ordinary skill in the art to which example embodiments belong.

Hereinafter, it will be described about a semiconductor package according to an exemplary embodiment of the present invention in conjunction with the accompanying drawings.

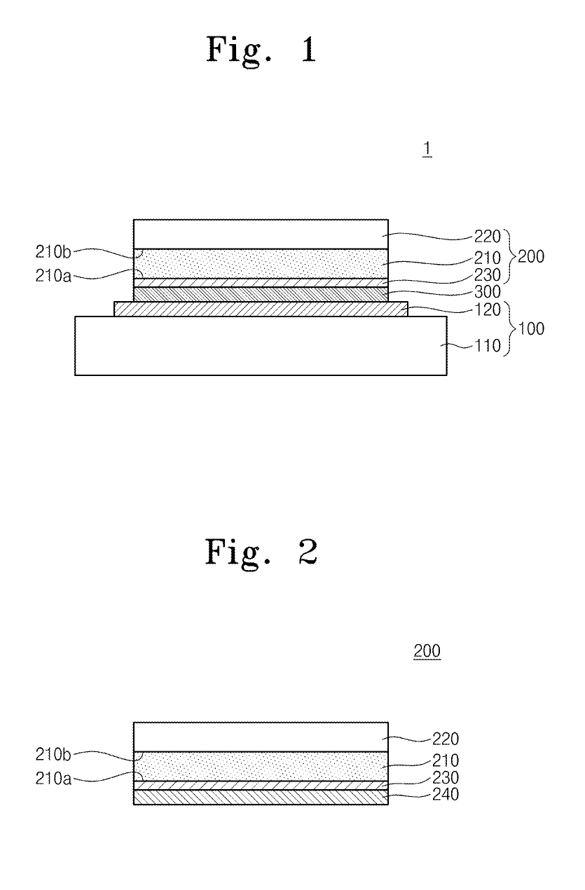

FIG. 1 is a cross-sectional view illustrating a semiconductor package according to an embodiment of the present invention. Referring to FIG. 1, the semiconductor package 1 may be a surface-mount device (SMD) that a die 200 is mounted on a package substrate 100.

The package substrate 100 may include a base substrate 110 and a lead frame 120 on the base substrate 110. The base substrate 110 may be a printed circuit board (PCB) or a wafer level substrate. The lead frame 120 may include a metal material, for example, copper (Cu), Iron (Fe) and/or an alloy of Nickel/Iron (Ni/Fe). A preform may be omitted on the lead frame 120.

A die 200 may include a silicon substrate 210, a semiconductor chip 220, and a first metal layer 230. The die 200 may have a plane of 500×500 μm ² or smaller. The silicon substrate 210 may be a substrate on which a natural oxide film is not formed. The silicon substrate 210 may have 100 to 200 μm, for example, 150 μm thickness. The semiconductor chip 220 may be disposed on a second surface 210b of the silicon substrate 210. The semiconductor chip 220 may include an integrated circuit, for example, a memory circuit, a logic circuit, or a combination thereof

The first metal layer 230 may be disposed on a first surface 210a of the die 200. The first metal layer 230 may include a first metal, for example, titanium, or chromium. For example, the first metal layer 230 may have 300 Å or smaller (e.g. 75 Å or smaller) thickness. For another example, the first metal layer 230 may be omitted.

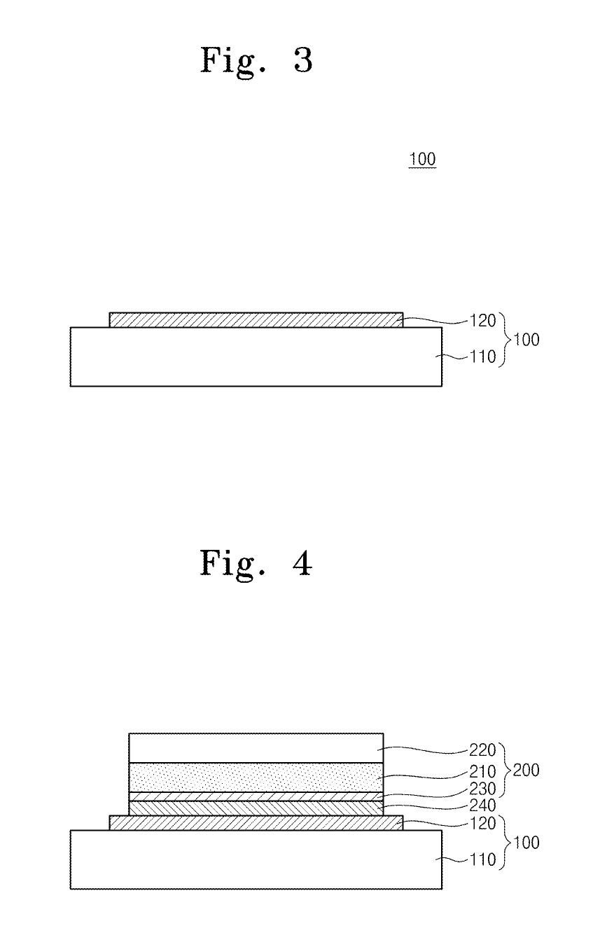

The adhesive layer 300 may be interposed between the first metal layer 230 and the lead frame 120. The adhesive layer 300 may attach the die 200 to the lead frame 120 of the package substrate 100. The adhesive layer 300 may include the same material (e.g. silicon) as that of the silicon substrate 210 and a second metal (e.g. gold) to be described in relation to FIG. 2. The adhesive layer 300 may further include the same material as that of the first metal layer 230.

The semiconductor package 1 including the adhesive layer 300 of an embodiment of the present invention may have higher bonding strength, lower bonding resistance and/or higher thermal stability between the die 200 and the semiconductor substrate 100, compared to a case of including an adhesive layer or a bump of an epoxy material

Hereinafter, a method of fabricating a semiconductor package according to an embodiment of the present invention is described in relation to the accompanying drawings.

FIGS. 2 to 5 are cross-sectional views illustrating a method of fabricating a semiconductor package according to an embodiment of the present invention. Description overlapping with that in relation to FIG. 1 will be omitted.

Referring FIG. 2, a semiconductor chip 220 may be formed on a second surface 210a of a silicon substrate 210. A grinding process may be performed on a first surface 210a of the silicon substrate 210. Thus, a thickness of the silicon substrate 210 may be reduced to 100 to about 200 μm thickness, for example, about 150 μm thickness. The first metal layer 230 may be formed by depositing a first metal, for example, titanium or chromium, on the first surface 210a of the silicon substrate 210. Deposition of the first metal layer 230 may be performed by e-beam evaporation. At this time, since the first metal layer 230 is deposited under a vacuum environment or a nitrogen atmosphere, a native oxide film may be not formed on the silicon substrate 210. Thus, semiconductor package 1 according to an embodiment of the present invention may have stronger adhesive strength. The first metal layer 230 may be deposited to have about 25 to about 300 Å thickness, for example, about 75 Å thickness. A bonding force between the silicon substrate 210 and a second metal layer 240 may be weak. As the first metal layer 230 is formed between the silicon substrate 210 and the second metal layer 240, the silicon substrate 210 and the first metal layer 230, and the first metal layer 230 and the second metal layer 240 may be favorably adhered. The second metal layer 240 may be formed by depositing a second metal (e.g. gold), which is different from that of the first metal layer 230, on the first metal layer 230. The second metal layer 240 may be deposited to have about 3,000 to 10,000 Å thickness, for example, 5,000 Å thickness. The die 200 may be formed by sawing the silicon substrate 210, the first metal layer 230, and the second metal layer 240.

Referring to FIG. 3, a package substrate 100 may be prepared. The package substrate 100 may include a base substrate 110 and a lead frame 120 on the base substrate 110. The base substrate 110 may be a printed circuit board (PCB) or a wafer level substrate. The lead frame 120 may include copper (Cu), iron (Fe), and/or a Nickel/iron (Ni/Fe) alloy. A preform may not be formed on the lead frame 120. Accordingly, the package substrate 100 may not include gold (Au) or aluminum (Al).

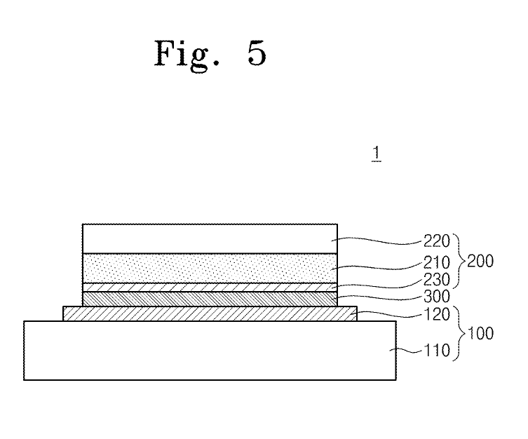

Referring to FIGS. 4 and 5 together, the die 200 may be mounted on the package substrate 100. The semiconductor package 1 may be formed by sequentially performing processes of FIGS. 4 and 5. For example, the die 200 may be disposed on the package substrate 100. The second metal layer 240 of the die 200 may be faced down towards the lead frame 120 to contact the lead frame 120. The adhesive layer 300 may be formed between the first metal layer 230 and the lead frame 120 by eutectic bonding between the silicon substrate 210 and the second metal layer 240. The adhesive layer 300 may attach the die 200 to the package substrate 100. The eutectic bonding process may be performed under a temperature condition of about 370 to about 450° C., for example, 420° C. When the eutectic bonding process is performed at a temperature lower than about 370° C., the adhesive layer 300 may not be formed because the temperature is lower than a eutectic temperature of the second metal and silicon. When the eutectic bonding process is performed at a temperature higher than about 450° C., the die 200 may be damaged by heat. For example, the die 200 may be broken or have electrical characteristics changed at a temperature of about 450° C. or higher. Due to the eutectic bonding, silicon atoms included in the silicon substrate 210 may pass through the first metal layer 230 to be moved to the second metal layer 240. The silicon atoms are combined with the second metal of the second metal layer 240 to form the adhesive layer 300. The first metal included in the first metal layer 230 may be moved to the second metal layer 240 by the silicon atoms. Accordingly, the first metal layer 230 may become extinct or have smaller thickness (e.g. about 300 Å or smaller, in particular about 75 Å) compared to a case before the adhesion is performed. The adhesive layer 300 may further include the first metal.

When the first metal layer 230 is thicker than about 300 Å, the silicon atoms included in the silicon substrate 210 are difficult to move to the second metal layer 240 and accordingly the adhesive layer 300 may not be formed. In order to form the adhesive layer 300, the preform may be formed on the lead frame 120 and a third metal layer (not shown) including an Au/Si alloy may be formed on the second metal layer 240. As the first metal layer 230 has about 25 to about 300 Å thickness, in the semiconductor package 1 according to an embodiment of the present invention, the adhesive layer 300 may be formed by the eutectic bonding without processes of forming the preform and the third layer. Thus, the die 200 may be easily combined with the package substrate 100. According to an embodiment of the present invention, as the third metal layer is omitted, a use amount of gold (Au) used for forming the adhesive layer 300 may be reduced. Since the adhesive layer 300 according to the embodiment is formed under the temperature condition of about 370 to about 450° C., damage to the semiconductor package 1 can be prevented.

In a semiconductor package according to an embodiment of the present invention, since a first metal layer has about 25 to about 300 Å thickness, an adhesive layer can be formed by eutectic bonding without a process of forming a preform or a third metal layer. Accordingly, a die can be easily mounted on the semiconductor package. In addition, an amount of gold (Au) used for forming the adhesive layer can be reduced. Since the adhesive layer according to an embodiment of the present invention is formed under a temperature condition of about 370 to about 450° C., damage to the semiconductor can be prevented.

A semiconductor package according to an embodiment of the present invention can have higher bonding strength, lower bonding resistance, and/or higher thermal stability between the die and the semiconductor package, compared to a semiconductor package including an adhesive layer or a bump of an epoxy material.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of fabricating a semiconductor package, comprising:
preparing a die including a first metal layer and a second metal layer which are sequentially stacked on a silicon substrate;
preparing a package substrate including a lead frame; and
forming an adhesive layer between the lead frame and the first metal layer to attach the die to the package substrate,
wherein the adhesive layer is formed by eutectic bonding of silicon substrate and the second metal layer.

2. The method of claim 1, wherein the adhesive layer comprises silicon and the same material as that of the second metal layer.

3. The method of claim 2, wherein the adhesive layer further comprises the same material as that of the first metal layer.

4. The method of claim 1, wherein forming of the adhesive layer comprises:
facing down the die on the package substrate and contacting the second metal layer to the lead frame; and
heating the die and the package substrate.

5. The method of claim 4, wherein the heating is performed under a temperature condition of about 370 to about 450° C.

6. The method of claim 1, wherein the preparing of the die comprises:
depositing titanium or chromium on the silicon substrate to form the first metal layer; and
depositing gold on the first metal layer to form the second metal layer.

7. The method of claim 1, wherein the first metal layer has about 25 to about 300 Å thickness.

8. The method of claim 1, wherein the second metal layer has about 3,000 to about 10,000 Å thickness.
